(19) United States
(12) Patent Application Publication
(10) Pub. No.: US 2026/0282415 A1
(43) Pub. Date: Sep. 17, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Shao-Ming YU, Hsinchu County (TW); Wei-Sheng YUN, Taipei City (TW); Tung Ying LEE, Hsinchu City (TW); YunYan CHUNG, Hsinchu City (TW); Chao-Ching CHENG, Hsinchu City (TW)

(73) Assignee: TAIWAN SEMICONDUCTOR MANUFACTURING COMPANY, LTD., Hsinchu (TW)

(21) Appl. No.: 19/076,328

(22) Filed: Mar. 11, 2025

(51) Int. Cl. H10D 30/43; H10D 30/01; H10D 62/10; H10D 62/13; H10D 64/23; H10D 64/60; H10D 86/00

(52) U.S. Cl. CPC H10D 30/43; H10D 30/014; H10D 62/102; H10D 62/121; H10D 62/151; H10D 64/251; H10D 64/60; H10D 86/201

(57) ABSTRACT

A method includes providing a stacked structure of alternating two-dimensional (2D) material layers and dielectric layers; selectively removing first portions of the dielectric layers around source/drain regions of the 2D material layers; forming contact layers wrapping around the source/drain regions of the 2D material layers; forming source/drain metals over the contact layers; selectively removing second portions of the dielectric layers around channel regions of the 2D material layers; forming a gate electrode wrapping around the channel region of the 2D material layers, wherein the gate electrode is positioned laterally between the source/drain metals.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrates schematic views of a semiconductor structure in accordance with some embodiments of the present disclosure.

FIGS. 2A-19C illustrate schematic perspective views and cross-sectional views of a semiconductor structure over a substrate in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

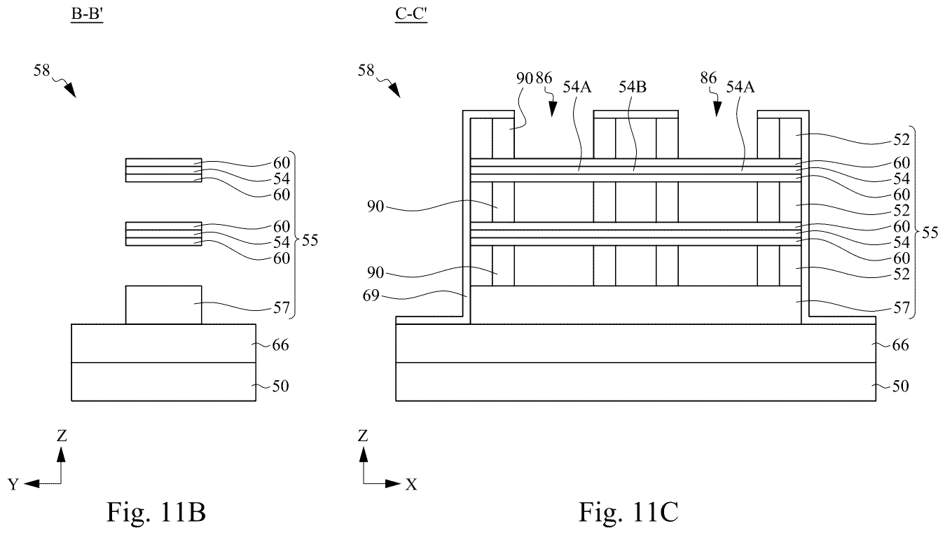

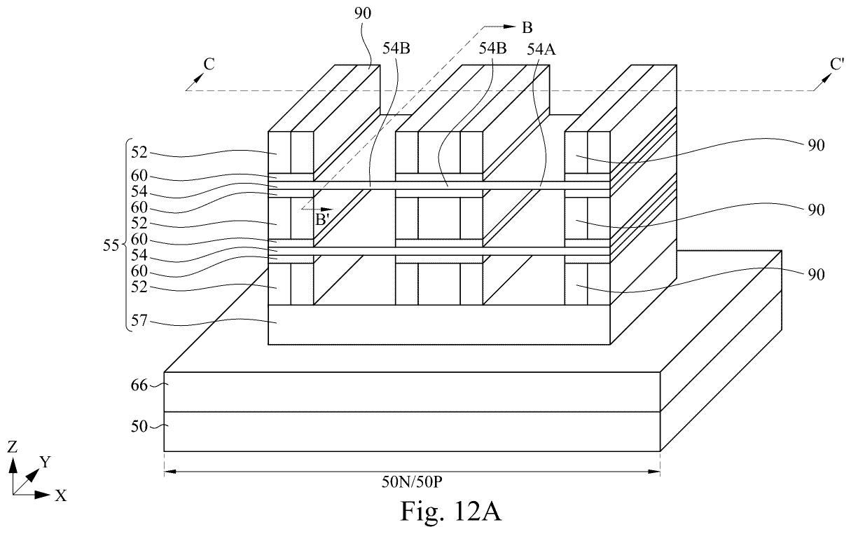

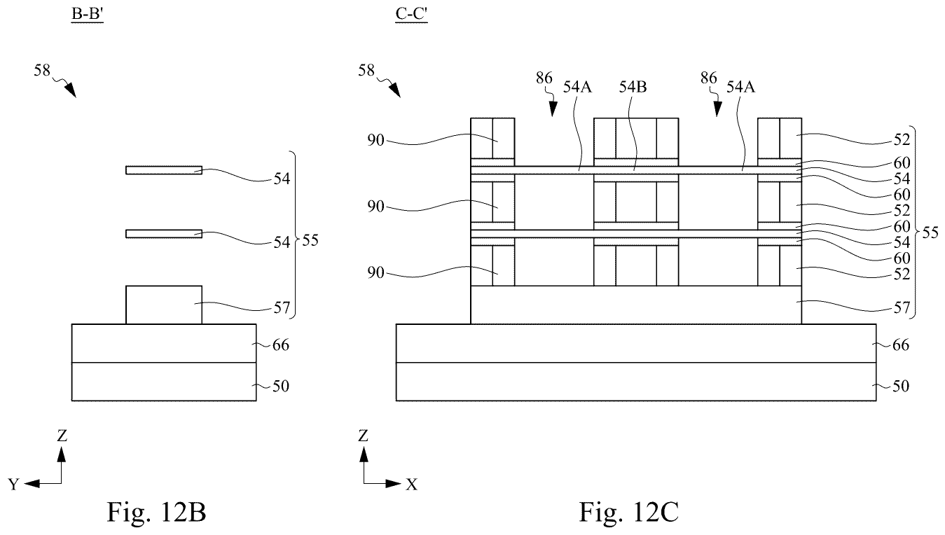

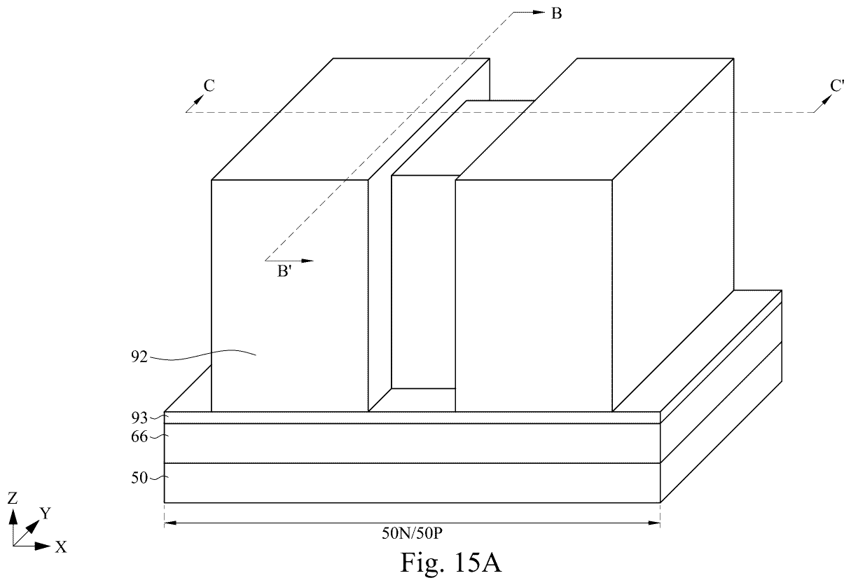

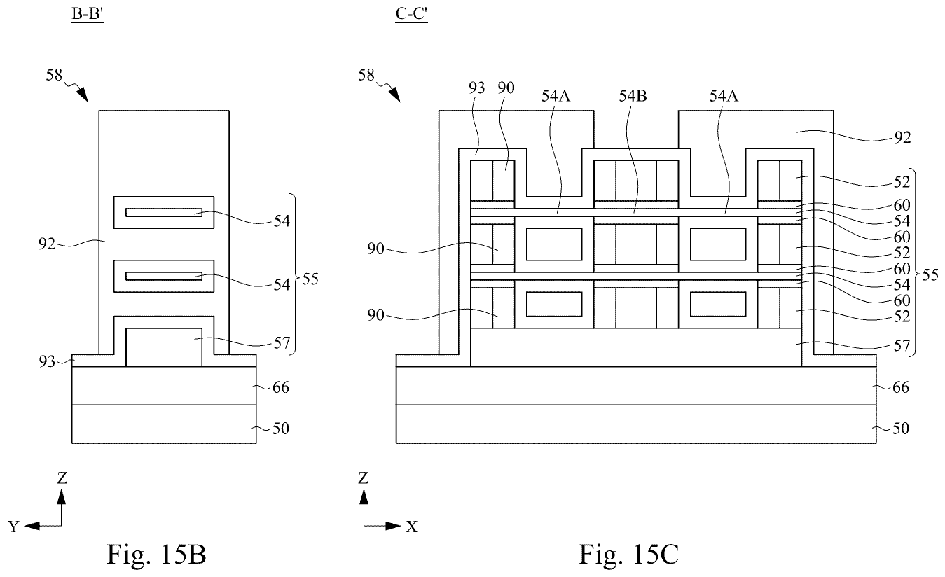

In semiconductor device fabrication of stacked 2D material nanosheet, source/drain metal is deposited only on the sidewalls of the active region (or oxide definition (OD)) pattern, which limits the contact area and degrades overall device performance. Therefore, the present disclosure in various embodiments provides a wraparound source/drain contact formation process, which increases the contact area between the 2D material source/drain region and the source/drain metal layer. Specifically, a protection layer (e.g., nanostructure 60 shown in FIGS. 11A-12C) can be formed to protect the channel area during the etching and sheet release processes in the source/drain area. Subsequently, a sheet release process (see FIG. 11A-11C) can be performed in source/drain area, creating a suspended nanosheet structure (e.g., source/drain region 54A) before the source/drain metal deposition (e.g., source/drain metals 92 shown in FIGS. 15A-15C). Subsequently, a specific dry etching (FIGS. 12A-12C) to pattern the protection layer and release the source/drain region 54A from the protection layer for the wraparound contact. The source/drain metal 92 can be formed over the source/drain region 54A to form a wraparound contact profile that maximizes the interaction between the source/drain 92 metal and the source/drain region 54A, which in turn allows for reducing resistance.

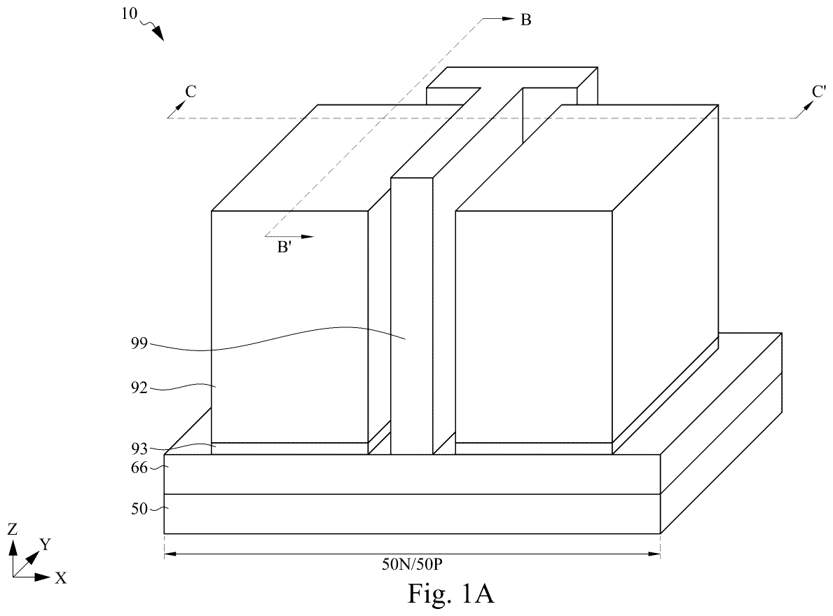

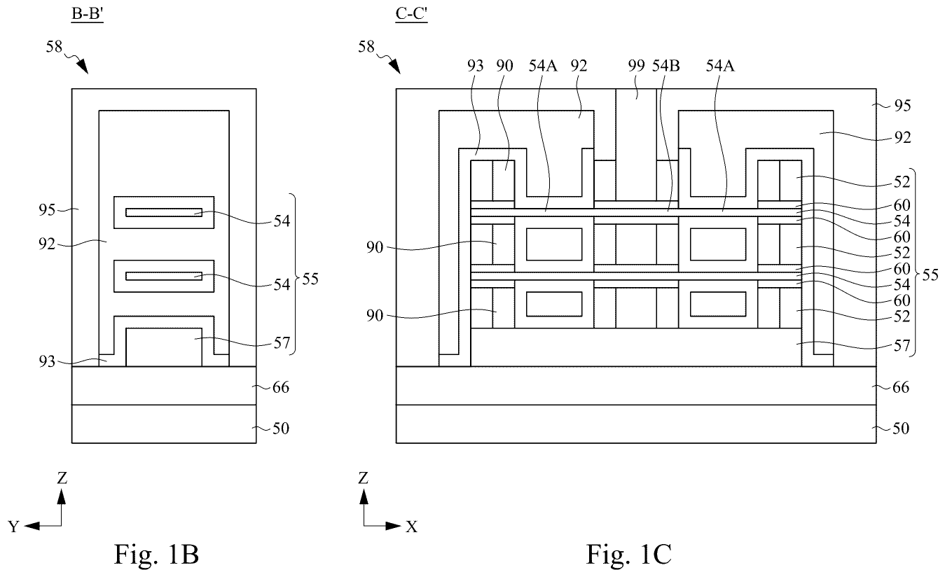

Reference is made to FIGS. 1A-1C. FIGS. 1A-1C illustrates schematic views of a semiconductor structure (e.g., transistor 10) in accordance with some embodiments of the present disclosure. The transistor 10 can be a multi-layered semiconductor device. As shown in FIG. 1A-1C, a substrate 50 can form the base of the transistor 10, made of a semiconductor material like silicon, silicon-on-insulator (SOI), or similar. In some embodiments, the substrate 10 can be doped to create n-type regions (50N) and p-type regions (50P) for forming complementary devices such as NMOS and PMOS transistors. Nanostructures 54 including 2D material can be formed over the substrate 50 and serve as the active regions (including channel region and source/drain region) of the device, enabling high electron mobility and low power consumption. Specifically, source/drain regions 54A are located at the ends of the nanostructure 54 and connected to source/drain metals 92 for establishing electrical pathways. In some embodiments, the source/drain metals 92 can be conductive materials like tungsten (W), cobalt (Co), or titanium (Ti), forming robust electrical contacts. A source/drain contact layer 93 can be formed to interpose between the source/drain regions 54A and the source/drain metal 92.

Inner spacers 90 can be positioned alongside the source/drain regions 54A to isolate them from the gate areas (e.g., gate electrode layer 99). In some embodiments, the inner spacer 90 can be made of a dielectric material like silicon nitride or silicon oxynitride, which in turn allows the inner spacers 90 for protecting the device during subsequent etching and processing steps. The gate structure including the permanent gate electrode layer 99 and gate dielectric layers 60 can be formed to wrap around the channel regions 54B in the nanostructures 54. In some embodiments, the gate dielectric layer 60 can include high-k material such as hafnium oxide (HfO₂) to enhance gate control and reduce leakage. The gate electrode layer 99 can include metal-containing materials like titanium nitride (TiN), tungsten (W), the like, or combinations thereof. In some embodiments, a dielectric layer 66 and a nanostructure 57 can serve as protective barriers during the fabrication process, preventing over-etching and preserving the underlying substrate and active regions. An interlayer dielectric (ILD) layer 95 covers and encapsulates the entire structure, providing electrical insulation between different layers and regions. In some embodiments, the ILD layer can be made of materials like silicon oxide, phospho-silicate glass (PSG), the like, or combinations thereof.

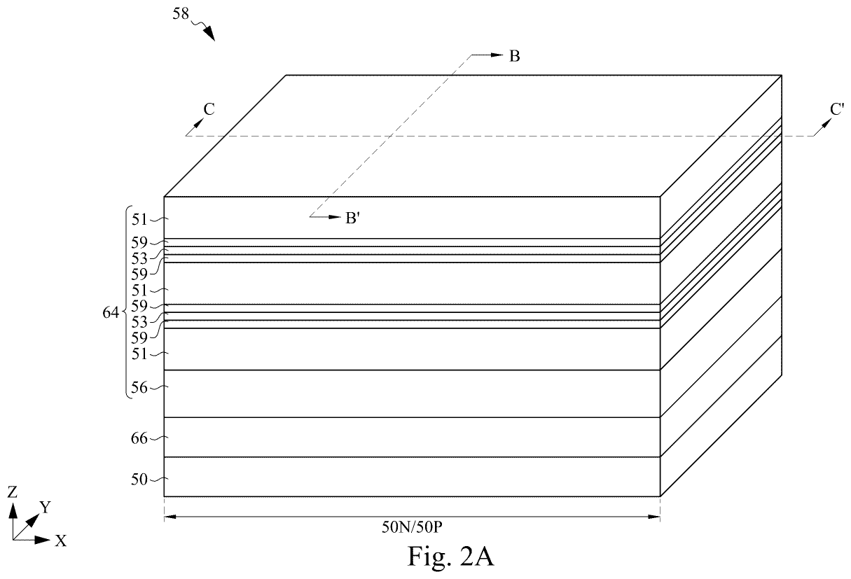

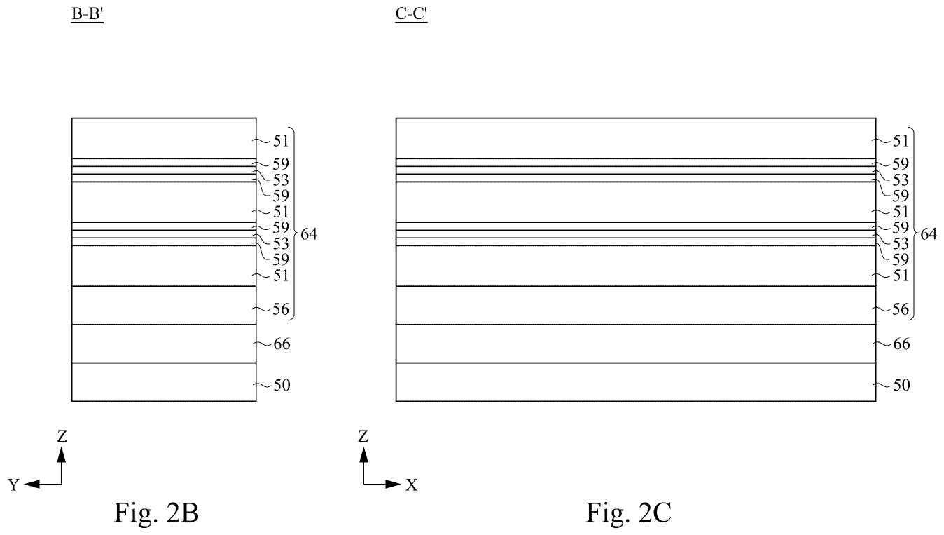

Reference is made to FIGS. 2A-19C. FIGS. 2A, 3A, 4A, 5A, 6A, 7A, 8A, 9A, 10A, 11A, 12A, 13A, 14A, 15A, 16A, 17A, 18A, and 19A illustrate schematic perspective views of a semiconductor structure over a substrate in accordance with some embodiments. FIGS. 2B, 3B, 4B, 5B, 6B, 7B, 8B, 9B, 10B, 11B, 12B, 13B, 14B, 15B, 16B, 17B, 18B, and 19B illustrate cross-sectional views obtained from reference cross-sections B-B′ in FIGS. 2A, 3A, 4A, 5A, 6A, 7A, 8A, 9A, 10A, 11A, 12A, 13A, 14A, 15A, 16A, 17A, and 18A. FIGS. 2C, 3C, 4C, 5C, 6C, 7C, 8C, 9C, 10C, 11C, 12C, 13C, 14C, 15C, 16C, 17C, 18C, and 19C illustrate cross-sectional views obtained from reference cross-sections C-C′ in FIGS. 2A, 3A, 4A, 5A, 6A, 7A, 8A, 9A, 10A, 11A, 12A, 13A, 14A, 15A, 16A, 17A, 18A, and 19A. It is understood that additional operations can be provided before, during, and after the processes shown by FIGS. 2A-19C, and some of the operations described below can be replaced or eliminated, for additional embodiments of the method. The order of the operations/processes may be interchangeable.

Reference is made to FIGS. 2A-2C. Reference is made to FIG. 2A. A substrate 50 can be provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

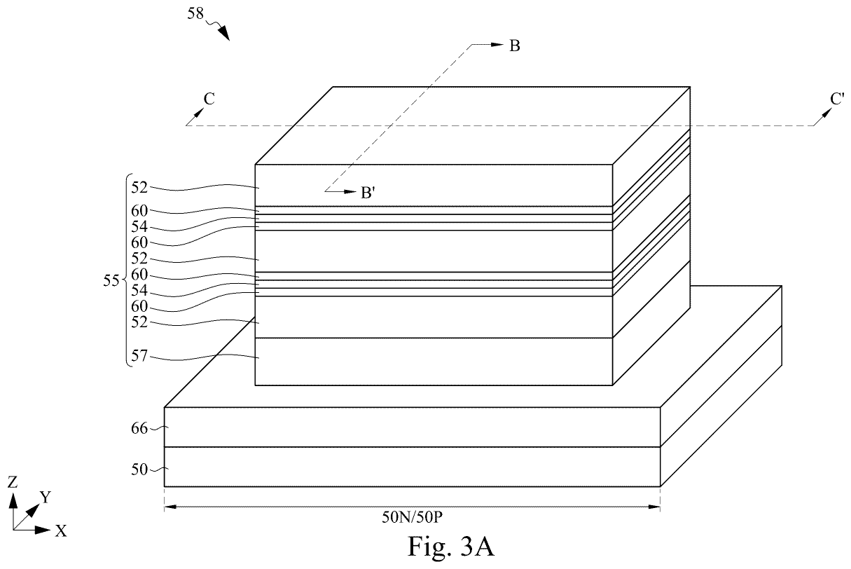

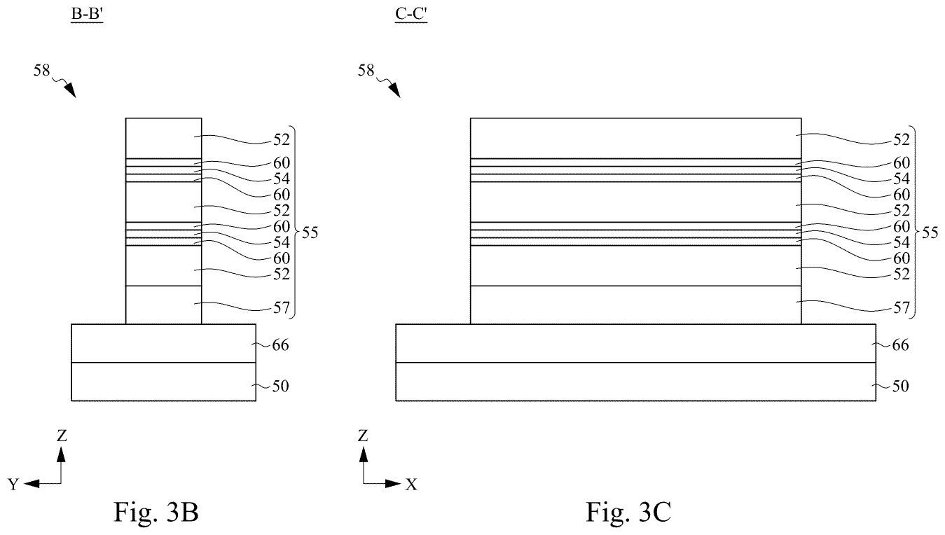

Further in FIG. 2A, a dielectric layer 66 can be disposed over the substrate 50. In some embodiments, the dielectric layer 66 can act as an etch stop during the OD etch (see FIGS. 3A-3C). In some embodiments, the dielectric layer 66 can act as an etch stop during etching, enhancing selectivity and protecting the substrate, which in turn prevents excessive etching of the substrate 50. In some embodiments, the deposition of the dielectric layer 66 can be performed using a conformal deposition process such as physical vapor deposition (PVD), CVD, ALD, or the like. In some embodiments, the dielectric layer 66 may be formed of metal oxide. In some embodiments, the dielectric layer 66 may be formed of a material having a dielectric constant greater than about 9 (e.g., high dielectric constant (high-k) material). For example, the dielectric layer 66 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric layer 66 may be formed of a homogenous material, or may have a composite structure including more than one layer.

Further in FIG. 2A, a multi-layer stack 64 can formed over the substrate 50. The multi-layer stack 64 can include a dielectric layer 56 and alternating layers of dielectric layers 51 and 2D material layers 53 over the dielectric layer 56. For purposes of illustration and as discussed in greater detail below, the dielectric layers 51 will be removed and the 2D material layers 53 will be patterned to form channel regions of nano-FETs in both the n-type region 50N and the p-type region 50P. In some embodiments, the channel regions of the n-type region 50N may have a different material composition than the channel regions of the p-type region 50P. The multi-layer stack 64 is illustrated as including two layers of each of the dielectric layers 51 and the 2D material layers 53 for illustrative purposes. In some embodiments, the multi-layer stack 64 may include any number of the dielectric layers 51 and the 2D material layers 53.

Further in FIG. 2A, the multi-layer stack 64 can further include protective layers 59 formed over a top surface and a bottom surface of the 2D material layer 53. In some embodiments, a thickness T1 of the dielectric layer 66 is more than twice a thickness T2 of the protective layer 59. By way of example and not limitation, the thickness T1 of the dielectric layer 66 can be in a range from about 5-20 nm, such as about 5, 6, 8, 10, 12, 14, 16, 18, or 20 nm. In some embodiments, the thickness of the protective layer 59 can be in a range from about 1-10 nm, such as about 1, 2, 3, 4, 5, 6, 7, 8, 9, or 10 nm. In some embodiments, a thickness T3 of 2D material layers 53 can be less than the thickness T2 of the protective layer 59. By way of example and not limitation, the thickness T3 of the 2D material layers 53 can be less than about 2 nm, such as about 2, 4, 6, 8, 10, 112, 14, 16, 18, or 20 angstrom.

In some embodiments, the dielectric layer 51/56 may be formed of a dielectric material, such as a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the dielectric layer 51 can be made of a different material than the dielectric layer 56. For example, the dielectric layer 51 may be made of silicon nitride while the dielectric layer 56 may be made of silicon oxide. In some embodiments, the dielectric layer 51 can be made of a same material as the dielectric layer 56. In some embodiments, the dielectric layer 51/56 can be formed using suitable deposition methods, including but not limited to chemical vapor deposition (CVD), plasma-enhanced chemical vapor deposition (PECVD), atomic layer deposition (ALD), plasma-enhanced atomic layer deposition (PEALD), or the like.

In some embodiments, the 2D material layers 53 may be formed of a 2D material In some embodiments, the 2D material layer 53 can be mono-layers of materials held together by chemical bonds and have outstanding electrical and physical properties. Mono-layers can be stacked on each other to form a 2D material layer that includes individual monolayers. In some embodiments, individual monolayers of graphene, thin layers of black phosphorus (also known as phosphorene), graphene analogues (such as silicene, gemanene, stannene, etc.), and/or boron nitride can be stacked to create the 2D material layer. In some embodiments, the 2D material layer 53 can include transition metal dichalcogenides (TMDs). The TMDs can have a general formula of MX₂, where M denotes a transition metal from, for example, periodic table column {IVB, VB, VIB} (e.g., molybdenum (Mo), tungsten (W), niobium (Nb), haftnium (Hf), or tantalum (Ta)), and X denotes an element from the group of {sulfur(S), selenium (Se), or tellurium (Te)}. In some embodiments, the 2D material layer 53 can be formed using suitable deposition methods, including but not limited to epitaxial growth, atomic layer deposition (ALD), CVD, PEVCD, molecular beam epitaxy (MBE), or metal deposition with subsequent chemical reaction. In some embodiments, forming the 2D material layer 53 can include a Langmuir-Blodgett process. In some embodiments, forming the 2D material layer 53 can include deposition processes and subsequent annealing processes to improve the material quality by increasing the domain size and reducing the defects.

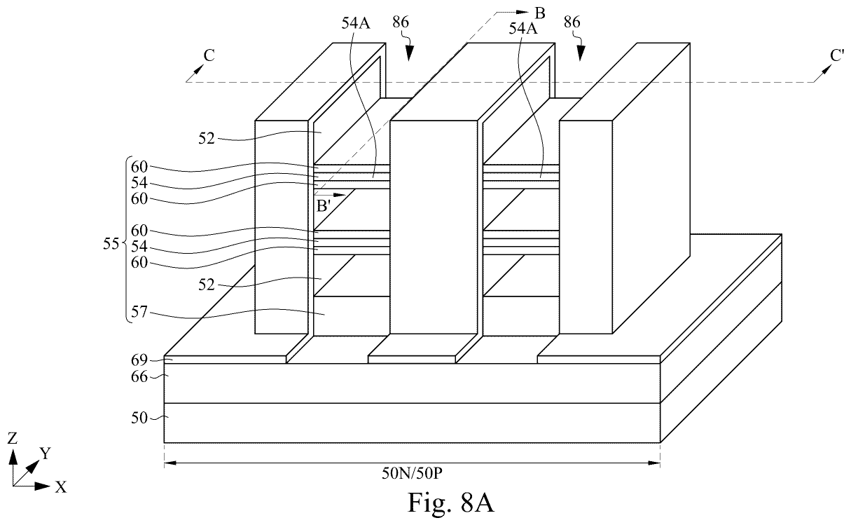

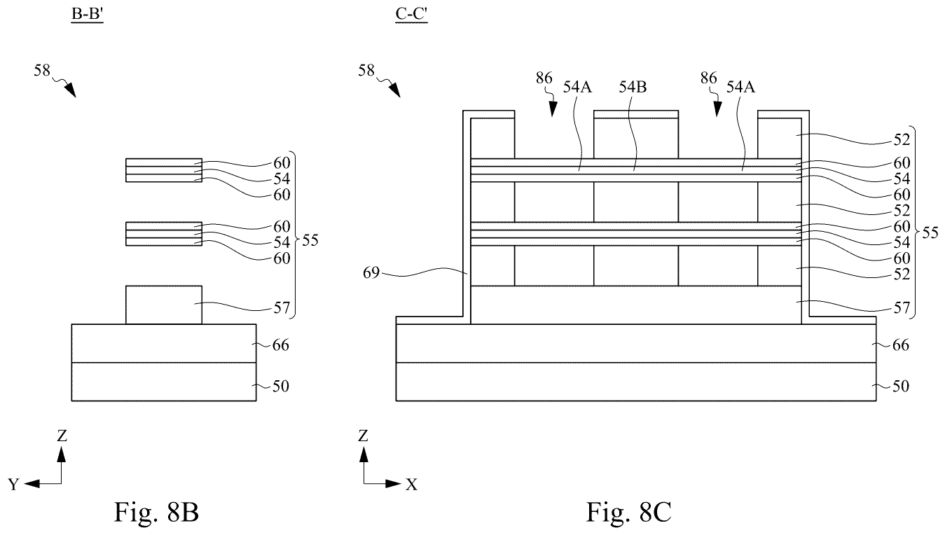

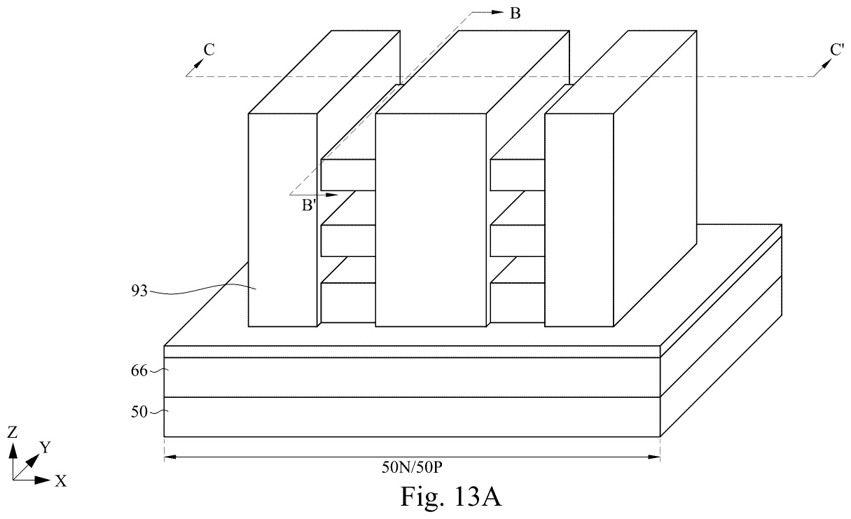

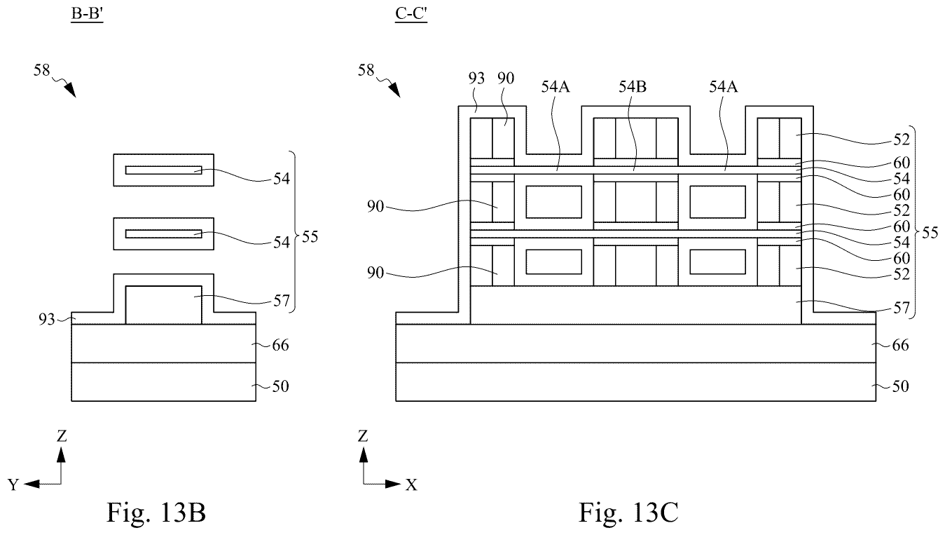

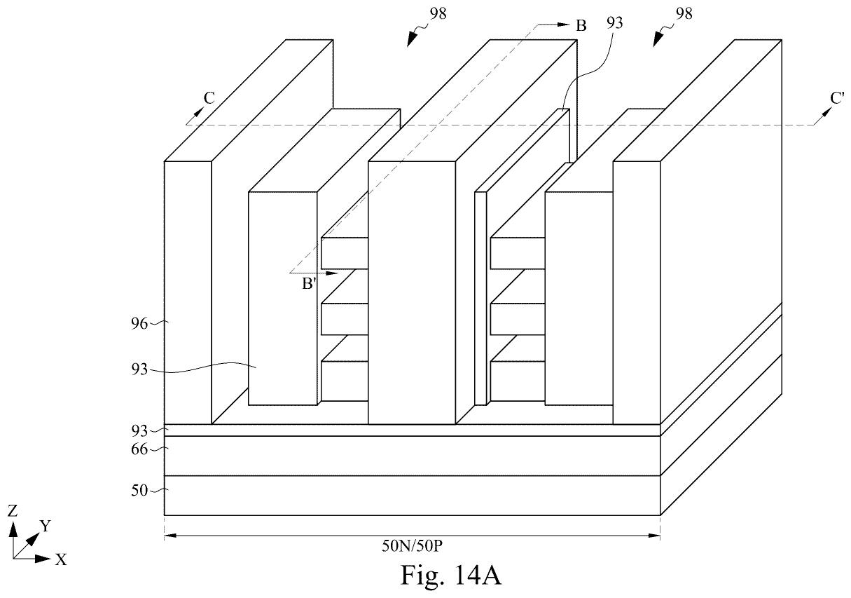

The protective layer 59 and the dielectric layer 51 may be materials having a high-etch selectivity to one another. As such, the dielectric layer 51 may be removed without damaging the 2D material layers 53 capping by the protective layer 59, thereby allowing the 2D material layers 53 to be released to form channel regions of the nano-FETs. Specifically, the protective layer 59 can serve multiple protective during various etching and processing steps, such as those shown in FIGS. 8A, 8B, and 13A-13C. The protective layer 59 can shield the underlying 2D material layers 53 during etching processes. The protective layer 59 can act as a barrier against etchants and other chemical processes that could otherwise degrade or unintentionally remove the 2D material layers 53. In some embodiments, the protective layer 59 can prevent unwanted chemical reactions between the 2D materials and other substances used in later processing steps. This isolation can help maintain the purity and electronic properties of the 2D materials. By protecting the integrity of the 2D material layers during manufacturing steps, the protective layer 59 can enhance the overall reliability of the semiconductor devices. Therefore, as the device features are etched deeper to form structures like trenches or vias, the protective layer 59 can ensure that the etching does not extend into the 2D material layers, preserving their functionality as part of the device's active regions. In processes aimed at releasing or defining the channel areas, the protective layer 59 can prevent over-etching or damage to the 2D materials.

In some embodiments, the protective layer 59 may be formed of metal oxide. In some embodiments, the protective layer 59 may be formed of a material having a dielectric constant greater than about 9 (e.g., high dielectric constant (high-k) material). For example, the protective layer 59 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The protective layer 59 may be formed of a homogenous material, or may have a composite structure including more than one layer. In some embodiments, the protective layer 59 can be made of a same material as the dielectric layer 66. In some embodiments, the protective layer 59 can be made of a different material than the dielectric layer 66. In some embodiments, the protective layer 59 can be formed using suitable deposition methods, including but not limited to chemical vapor deposition (CVD), plasma-enhanced chemical vapor deposition (PECVD), atomic layer deposition (ALD), plasma-enhanced atomic layer deposition (PEALD), or the like.

Reference is made to FIGS. 3A-3C. Nanostructures 55 are formed in the multi-layer stack 64 and over the dielectric layer 66, by etching trenches 58 in the multi-layer stack 64 to expose the dielectric layer 66. The etching may be any acceptable etch process, such as a reactive ion etch (RIE), neutral beam etch (NBE), the like, or a combination thereof. The etching may be anisotropic. The nanostructures 55 may be patterned by any suitable method. For example, the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures 55.

Forming the nanostructures 55 by etching the multi-layer stack 64 may further define nanostructures 52 from the dielectric layers 51, nanostructures 54 from the 2D material layers 53, a nanostructure 57 from the dielectric layer 56, and the nanostructures 60 from the protective layers 59. The nanostructures 52, 54, 57, and 60 can be collectively referred to as the nanostructures 55. In some embodiments, the nanostructure 55 can be interchangeable referred to as a fin structure. In some embodiments, widths of the nanostructure 55 in the n-type region 50N may be greater or thinner than the nanostructure 55 in the p-type region 50P. In other embodiments, the nanostructures 55 may have tapered sidewalls such that a width of each of the nanostructures 55 continuously increases in a direction towards the dielectric layer 66. In such embodiments, each of the nanostructures 55 may have a different width and be trapezoidal in shape.

In some embodiments, the dielectric layer 66 can act as a barrier that selectively stops the etching process at a predefined depth, ensuring that the etching does not proceed beyond a certain point, maintaining the integrity of the underlying substrate 50 or other layers.

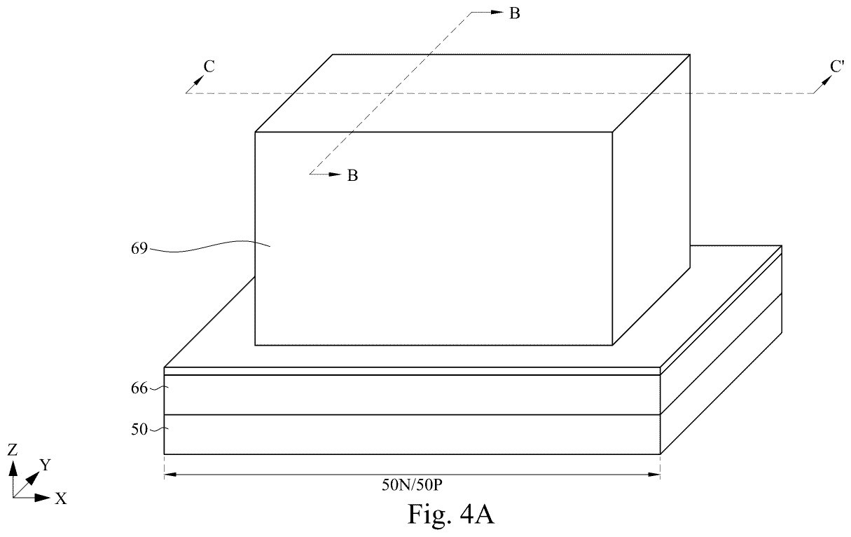

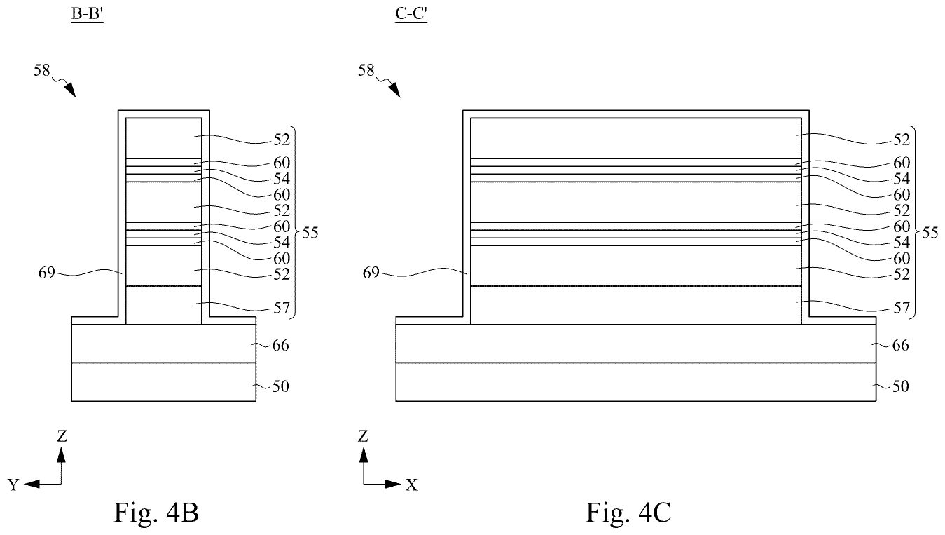

Reference is made to FIGS. 4A-4C. A mask layer 69 can be conformally formed over the nanostructures 55 (i.e., a combination of nanostructures 52, 54, 57, and 60) during etching processes, ensuring that specific regions are exposed for removal. The mask layer 69 can define source/drain regions 54A (see FIGS. 8A-12C) that are exposed by forming openings 86 through the mask layer 69. The mask layer 69 can ensure removal without affecting other layers, such as the protective layers 59, dielectric layers 51/56, or the underlying substrate 50. The mask layer 69 can later be removed or replaced, depending on the processing stage.

In some embodiments, the mask layer 69 may be formed of metal oxide. In some embodiments, the mask layer 69 may be formed of a material having a dielectric constant greater than about 9 (e.g., high dielectric constant (high-k) material). For example, the mask layer 69 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The mask layer 69 may be formed of a homogenous material, or may have a composite structure including more than one layer. In some embodiments, the mask layer 69 can be made of a same material as the nanostructure 60. In some embodiments, the mask layer 69 can be made of a different material than the nanostructures 60. In some embodiments, the mask layer 69 can be formed using suitable deposition methods, including but not limited to chemical vapor deposition (CVD), plasma-enhanced chemical vapor deposition (PECVD), atomic layer deposition (ALD), plasma-enhanced atomic layer deposition (PEALD), or the like.

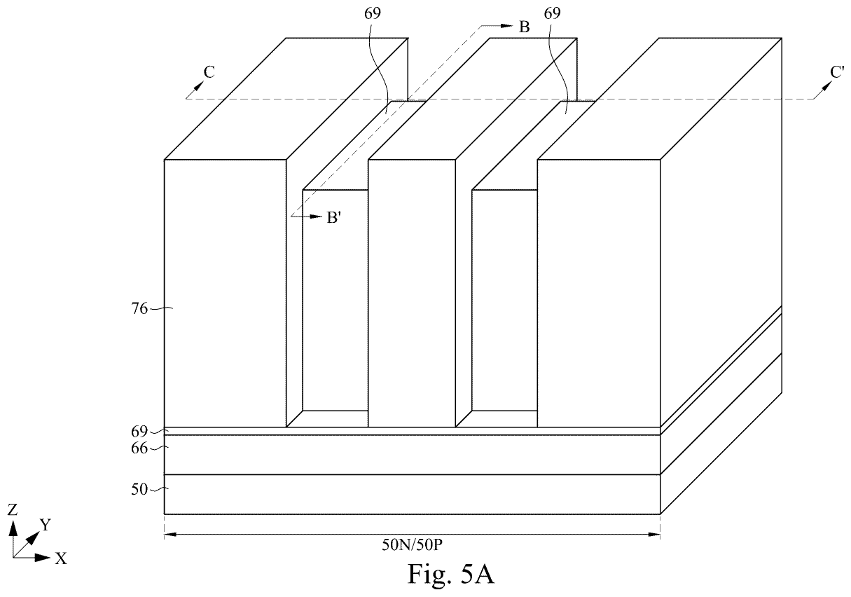

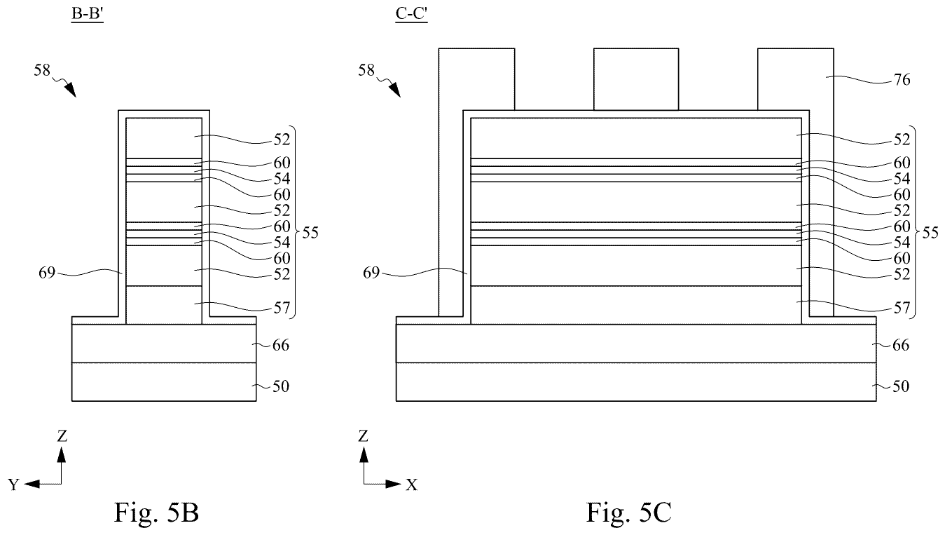

Reference is made to FIGS. 5A-5C. A mask layer 76 can be formed over the mask layer 69 and along sidewalls of the nanostructures 55 and the dielectric layer 66. To form the mask layer 76, first, the mask layer 76 can be formed on the dielectric layer 66 and/or the nanostructures 55. The mask layer 76 can include photo materials with a variety of light-sensitive substances, chosen based on their application. These materials can be photoresists, which include polymers that alter their solubility upon exposure to light, such as ultraviolet (UV) light. In some embodiments, there are two types of photoresists featuring positive and negative tone characteristics. Specifically, the positive tone photoresists can become more soluble where they are exposed to light. During development, the exposed areas are dissolved and washed away, leaving only the unexposed regions in place, allowing for pattern formation, as the remaining photoresist protects the underlying substrate where it is not exposed. In contrast, negative tone photoresists can become less soluble upon light exposure. The unexposed parts can be removed during the development process, while the exposed regions remain intact. These materials are useful for creating patterns where the exposed areas need to be retained.

In some embodiments, the mask layer 76 may include, for example, silicon oxide, silicon nitride, a combination thereof, or the like, and may be deposited or thermally grown according to acceptable techniques. In some embodiments, the mask layer 76 may include, for example, a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The mask layer 76 may be deposited by physical vapor deposition (PVD), CVD, sputter deposition, or other techniques for depositing the selected material. The mask layer 76 may be made of other materials that have a high etching selectivity from the etching of the mask layer 69.

Subsequently, the mask layer 76 may be patterned using acceptable photolithography and etching techniques, and thus the mask layer 76 can cover respective channel regions of the nanostructures 54. The mask layer 76 may also have a lengthwise direction substantially perpendicular to the lengthwise direction of respective multi-layer stacks 64. In some embodiments, the mask layer 76 can be removed following the formation of the source/drain regions of the device, allowing mask layer 76 to function as a temporary structure, referred to as a “dummy gate layer.” In some embodiments, the mask layer 76 can be interchangeable referred to as a dummy gate layer, a dummy gate strip, a dummy gate pattern, a dummy gate line, or a dummy gate structure. By fulfilling this role, the dummy gate layer can be integral to the execution of the replacement gate (RPG) process, which is a phase in semiconductor device fabrication. During the RPG process, the temporary dummy gate layer can facilitate the protection and definition of the underlying active regions until it is replaced with a permanent gate material.

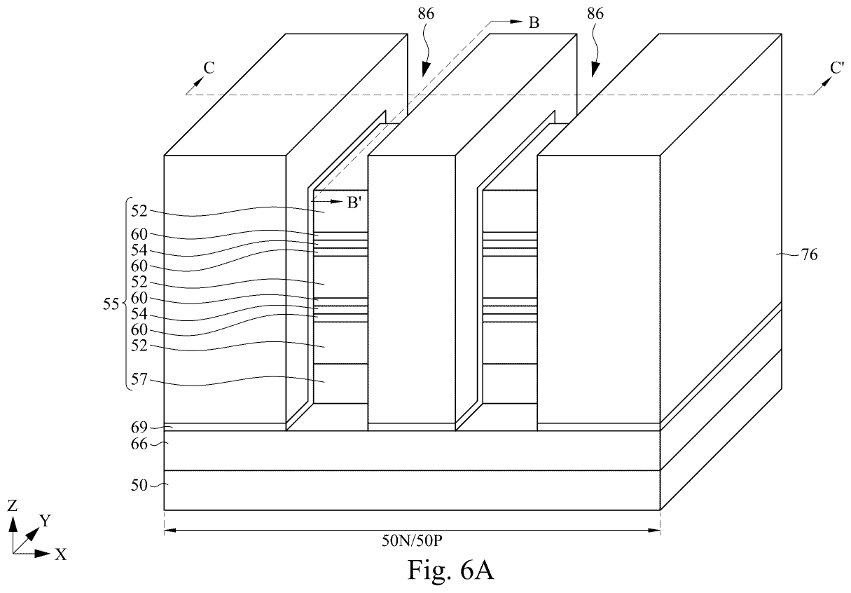

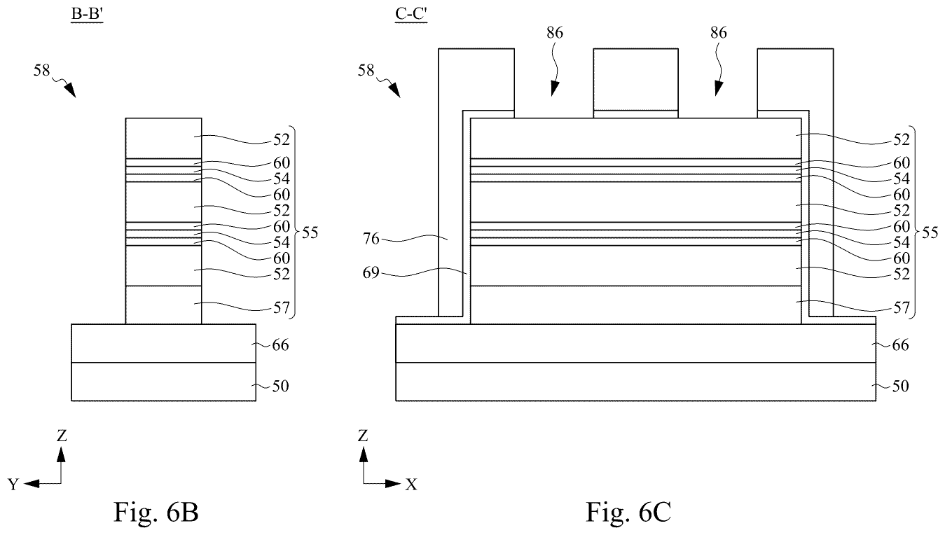

Reference is made to FIGS. 6A-6C. Openings 86 can be formed in the mask layer 69 to expose the nanostructures 55. In some embodiments, portions of the nanostructures 54 that overlap with the openings 86 can be considered as source/drain regions 54A. The openings 86 may extend through the mask layer 69 and stop at the dielectric layer 51. As illustrated in FIGS. 6A and 6C, a top surface of the dielectric layer 51 can be exposed in the openings 86. The openings 86 may be formed by etching the mask layer 69 using anisotropic etching processes, such as RIE, NBE, or the like. The mask layer 76 can mask portions of the mask layer 69 during the etching processes used to form the openings 86. A single etch process or multiple etch processes may be used to etch each layer of the mask layer 69.

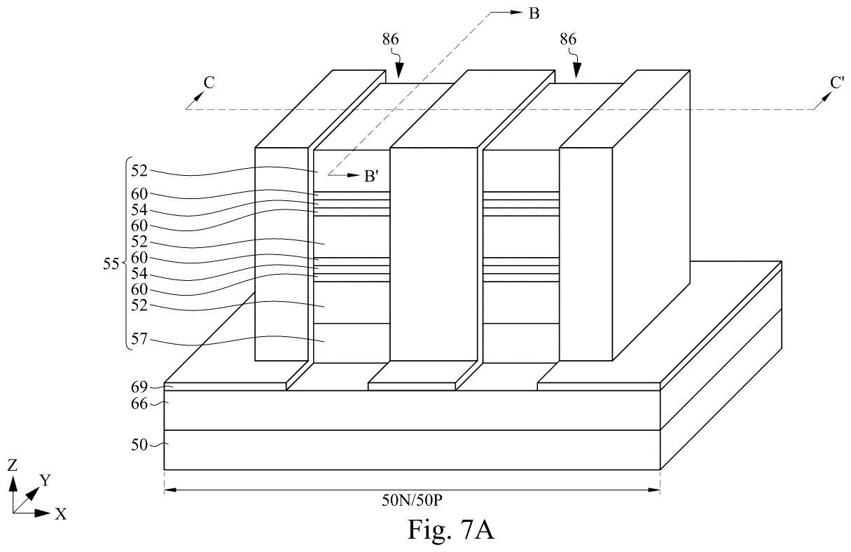

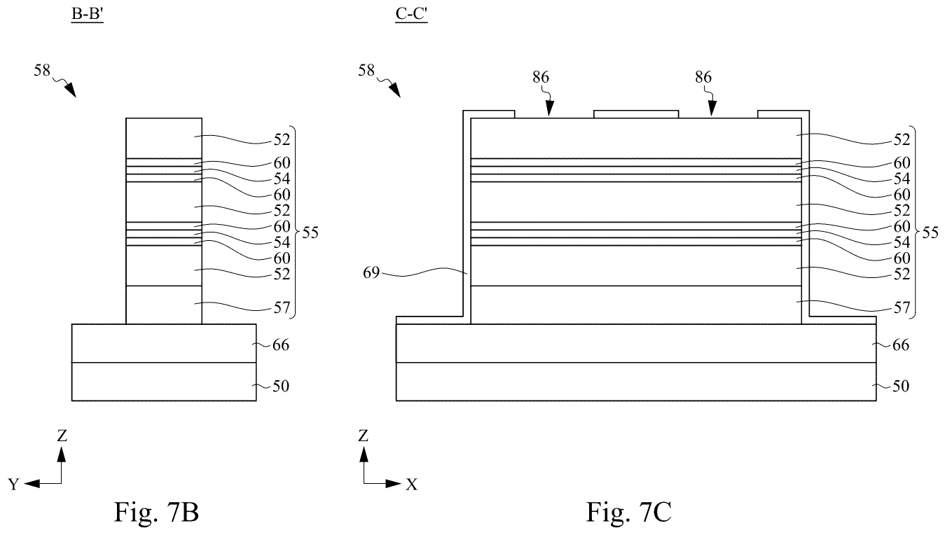

Reference is made to FIGS. 7A-7C. The mask layer 76 can be removed by a removal process. The removal process can be controlled to avoid damage to underlying layers and to maintain the integrity of the semiconductor device. In some embodiments, if the mask layer 76 is formed of light-sensitive substances like photoresists, the mask layer 76 can be removed using a process, such as a photoresist stripping. The stripping process can include chemical solutions, such as organic solvents (e.g., acetone or NMP), which dissolve the photoresist. Alternatively, a plasma etching process (ashing) can be used, where oxygen plasma can be employed to effectively remove the photoresist by breaking down its polymer chains. In some embodiments, if the mask layer 76 is formed of silicon oxide, silicon nitride, the like, or a combination thereof, the mask layer 76 can be removed using wet or dry etching techniques specific to these materials. For silicon oxide, hydrofluoric acid (HF) or buffered oxide etch (BOE) can be used as a wet etchant. Silicon nitride can be removed using phosphoric acid in a hot bath or by reactive ion etching (RIE) using fluorine-based gases. The selection of etching method depends on the layer thickness and the need to preserve underlying structures. In some embodiments, if the mask layer 76 is formed of amorphous silicon, polysilicon, polycrystalline silicon-germanium (Poly-SiGe), or the like, the mask layer 76 can be removed using a selective etch with a dry or wet etching process. For amorphous silicon and polysilicon, dry etching using chlorine or HBr-based plasma can be effective. Wet etching methods may include solutions containing potassium hydroxide (KOH) or tetramethylammonium hydroxide (TMAH). Poly-SiGe can be removed using chemical etching solutions like a mixture of nitric acid (HNO₃) and hydrofluoric acid (HF), or by using specialized plasma etching tailored for silicon-germanium alloys.

Reference is made to FIGS. 8A-8C. The nanostructures 52 in source/drain regions exposed by the mask layer 69 can be removed in an etching process to expand the openings 86. Each opening 86 can expose and/or overlies portions of the source/drain regions 54A on the nanostructures 54. The nanostructures 52 can be etched by any acceptable etching process that selectively etches the material of the nanostructures 52 at a faster rate than the material of the nanostructures 54, the nanostructures 60, and the nanostructure 57. In some embodiments, the etching may be isotropic. For example, when the nanostructures 52 can be formed of silicon nitride and/or silicon oxide and the nanostructures 60 and/or 57 can be formed of high-k dielectric material, the etching process may be a dry etch using carbon tetrafluoride (CF₄) gas or the like. In some embodiments, the removing of the remaining portions of the nanostructures 52 can be interchangeably referred to as a source/drain releasing process.

In some embodoiments, the high-k dielectric material in the nanostructures 60 can act as a protective barrier for the source/drain region 54A during etching. In other words, during the removal of the nanostructures 52, the nanostructures 60 can act as etch stop layers, halting the etch process to protect the underlying and adjacent layers, preventing over-etching and ensuring that the source/drain regions 54A and channel regions 54B in the nanostructures 54 are not damaged.

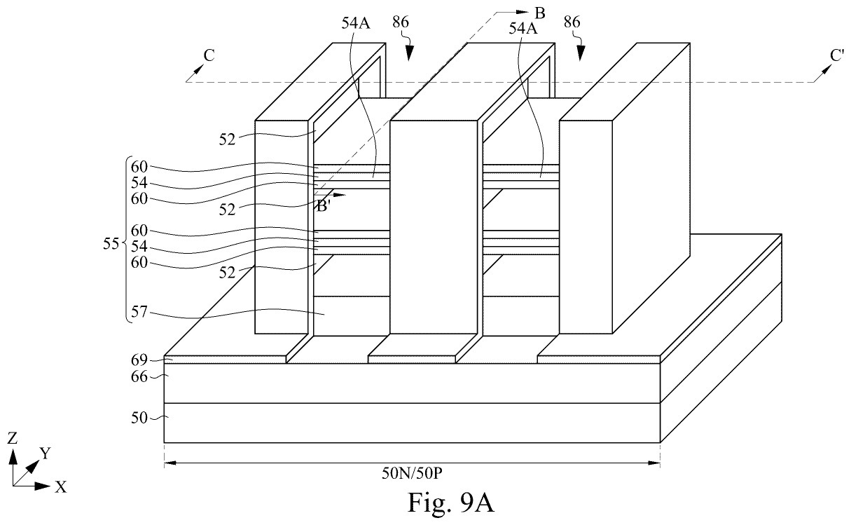

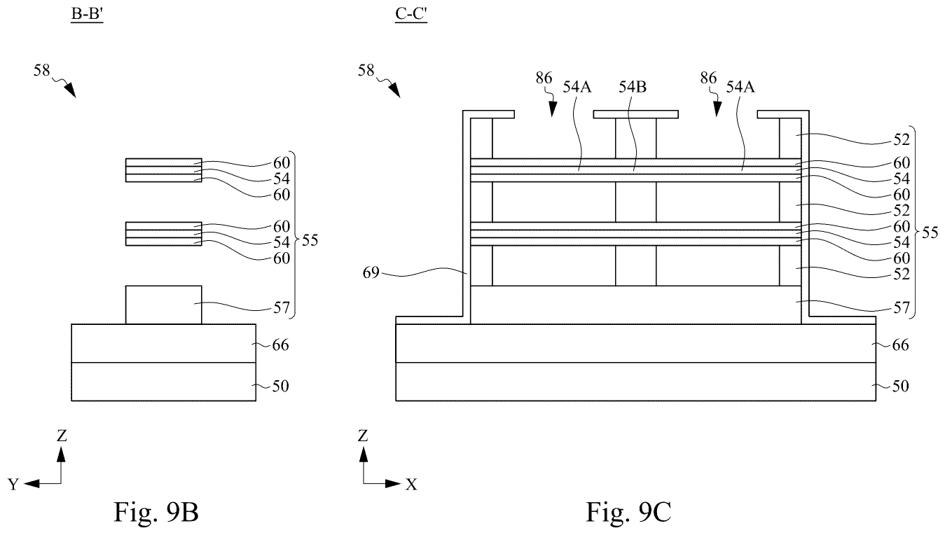

Reference is made to FIGS. 9A-11C. Inner spacers 90 (see FIG. 11C) can be formed on sidewalls of the etched portions of the nanostructures 52, e.g., those sidewalls exposed by the openings 86. As will be subsequently described in greater detail, source/drain metals 92 (see FIGS. 15A-15C) will be subsequently formed in the openings 86, and the nanostructures 52 will be subsequently replaced with corresponding gate structures, such that the inner spacers 90 can act as isolation features between the subsequently formed source/drain metals 92 and the subsequently formed gate structures. Further, the inner spacers 90 may be used to substantially prevent damage to the subsequently formed source/drain metals 92 by subsequent etching processes, such as etching processes used to subsequently remove the nanostructures 52. In some embodiments, the inner spacers 90 can be interchangeably referred to lower gate spacers.

As shown in FIGS. 9A-9C, as an example to form the inner spacers 90, the openings 86 can be laterally expanded. Specifically, portions of the sidewalls of the nanostructures 52 exposed by the openings 86 may be recessed. Although sidewalls of the nanostructures 52 are illustrated as being straight, the sidewalls may be concave or convex. The sidewalls may be recessed by any acceptable etching process, such as one that is selective to the material of the nanostructures 52 (e.g., selectively etches the material of the nanostructures 52 at a faster rate than the material of the nanostructures 54 and 60). The etching may be isotropic. In some embodiments, the etching process may be a dry etch using tetramethylammonium hydroxide (TMAH), ammonium hydroxide (NH₄OH), or the like. In some embodiments, the etching process may be a dry etch using a fluorine-based gas such as hydrogen fluoride (HF) gas or carbon tetrafluoride (CF₄) gas. In some embodiments, the same etching process may be continually performed to both form the openings 86 and recess the sidewalls of the nanostructures 52.

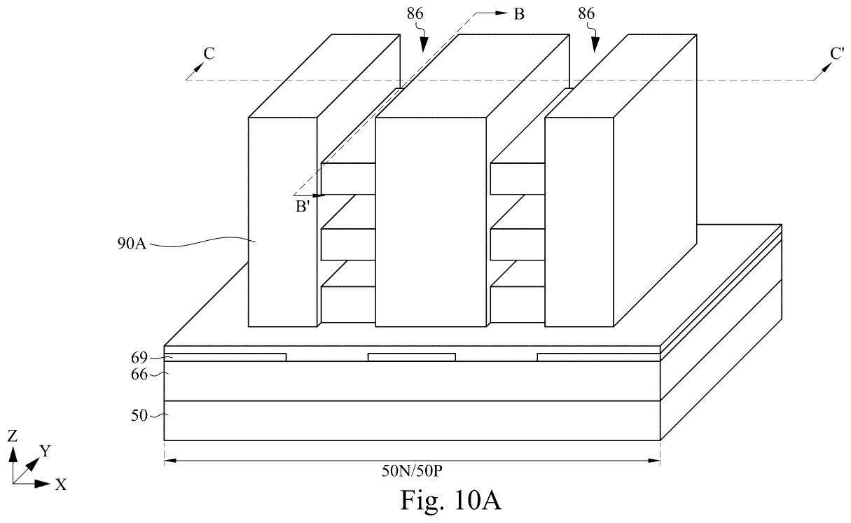

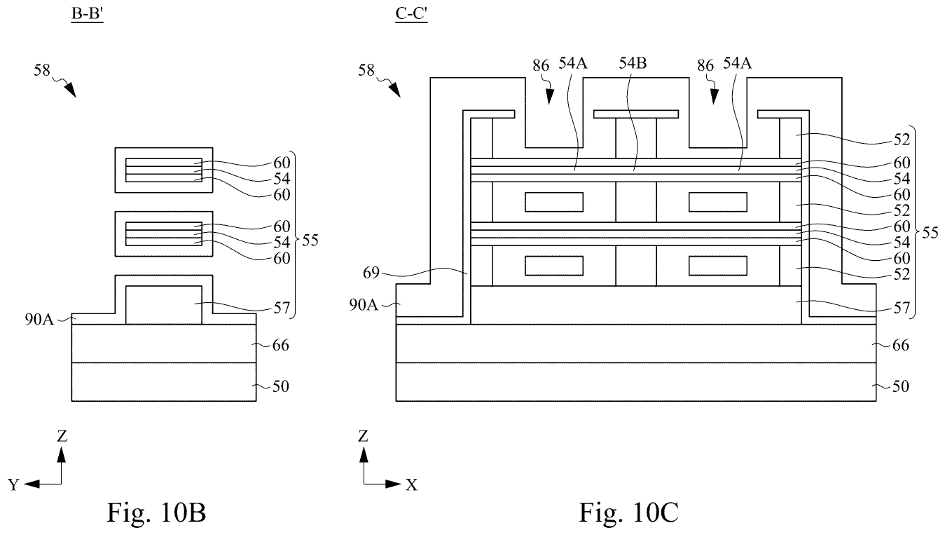

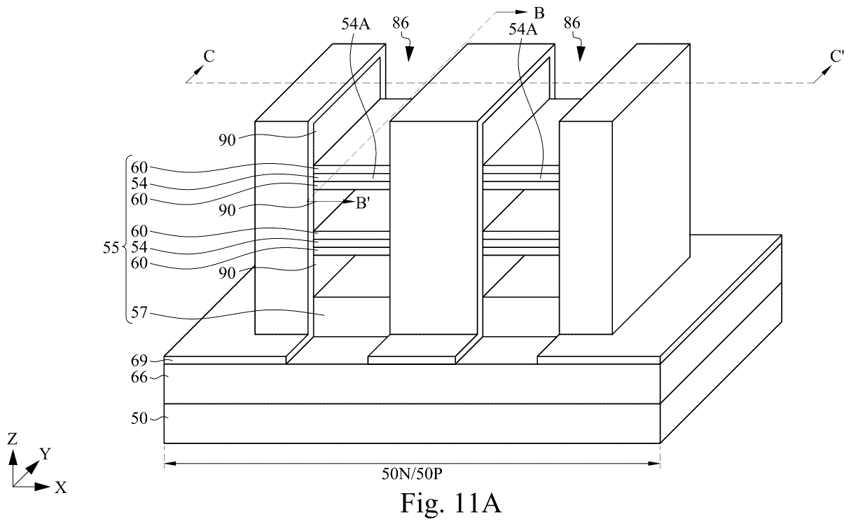

As shown in FIGS. 10A-10C, the inner spacers 90 (see FIG. 11C) can then be formed by conformally forming an insulating material 90A and subsequently etching the insulating material 90A. The insulating material 90A may be silicon nitride or silicon oxynitride, although any suitable material, such as low-dielectric constant (low-k) materials having a k-value less than about 3.5, may be utilized. In some embodiments, the material of the insulating material 90A can be selected from a group including SiO₂, Si₃N₄, SiON, SiOC, SiOCN base dielectric material, air gap, or combinations thereof. The insulating material 90A may be deposited by a conformal deposition process, such as ALD, CVD, or the like.

As shown in FIGS. 11A-11C, after the deposition of the insulating material 90A, an anisotropic etching process may be performed to trim the deposited insulating material 90A, such that portions of the insulating material 90A on the etched sidewalls of the nanostructures 52 can be left. After the trimming process, the remaining portions of the insulating material 90A can be denoted as the inner spacers 90. In some embodiments, the etching process may be a dry etch such as a RIE, a NBE, or the like. Although the sidewalls of the inner spacers 90 are illustrated as being straight, the sidewalls of the inner spacers 90 may be concave or convex.

Reference is made to FIGS. 12A-12C. The mask layer 69 and the protective layer 59 exposed in the openings 86 can be removed. Therefore, the source/drain regions 54A are exposed by removing the mask layer 69 and protective layer 59 within the openings 86, ensuring proper contact with the subsequently deposited source/drain metal 92 (see FIGS. 15A-15C). When addressing the removal of the mask layer 69 and the protective layer 59, both layers can be removed in one integrated process or sequentially in separate processes. If the mask layer 69 and the protective layer 59 are made of the same material, such as a metal oxide, it is possible to remove both layers concurrently using a single unified process. For the metal oxide layers, a chemical wet etching process can be utilized, employing an etchant that selectively targets the metal oxide. A choice might be a buffered oxide etch (BOE) or hydrofluoric acid (HF) if it's compatible with the materials present. Alternatively, dry etching methods such as plasma etching with fluorine-based gases can effectively remove metal oxide layers. This process can leverage reactive ions to break chemical bonds within the metal oxide, facilitating the removal of both layers simultaneously.

In some embodiments, the removal of the mask layer 69 and the protective layer 59 can be performed sequentially, when separate control over the etching of each layer is required, or when they are made of different materials. Initially, the mask layer 69 can be etched away using a process tailored to its material composition. For instance, if the mask layer is a specific type of metal oxide, a corresponding etching method using an appropriate chemical or plasma process will be employed. Subsequently, the protective layer 59 can be etched using a different technique.

Reference is made to FIGS. 13A-13C. A source/drain contact layer 93 can be conformally formed over the structure as depicted in FIGS. 12A-12C. The source/drain contact layer 93 can wrap around the source/drain regions 54A within the openings 86 and extends over structural components such as the inner spacer 90, the dielectric layer 66, and the nanostructures 52. By conformally coating these elements, the source/drain contact layer 93 can ensures a robust interface for subsequent processing steps, enhancing the overall integrity and performance of the device. In some embodiments, the source/drain contact layer 93 can include titanium nitride (TiN), tantalum nitride (TaN), tungsten nitride (WN), niobium nitride (NbN), aluminum nitride (AlN), the like, or combinations thereof. For example, the source/drain contact layer 93 can be made of a titanium-containing material. In some embodiments, the application of the source/drain contact layer 93 can be achieved through an atomic layer deposition (ALD) process. This process can include the alternate introduction of precursor gases, facilitating layer-by-layer growth that ensures comprehensive coverage even across geometries like those presented by the source/drain regions 54A, the inner spacer 90, the dielectric layer 66, and the nanostructures 52. In some embodiments, the source/drain contact layer 93 can wrap around four sides of the nanostructure 54. In some embodiments, the source/drain contact layer 93 can be interchangeable referred to as a metal contact, a metal film, a metal layer, a barrier layer, or a conductive layer.

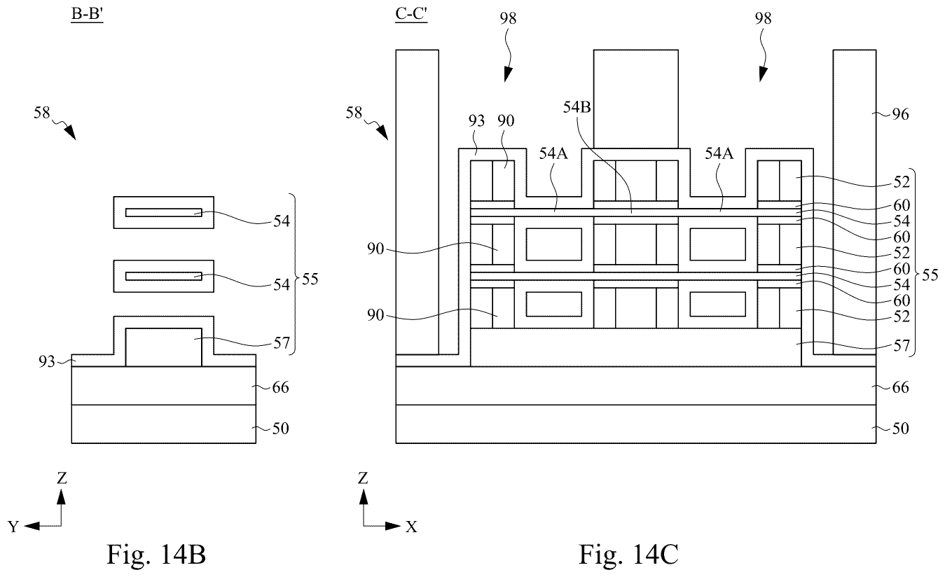

Reference is made to FIGS. 14A-14C. A mask layer 96 can be formed over the structure as shown in FIGS. 13A-13C. The mask layer 96 can be applied atop the source/drain contact layer 93 and play a role in defining subsequent semiconductor device features. In some embodiments, the mask layer 96 can utilizes photo materials that include light-sensitive substances, such as photoresists. These photoresists can alter their solubility in response to exposure to specific light wavelengths, such as ultraviolet (UV) light, enabling the intricate patterning of the substrate. The mask layer 96 can employ two types of photoresists: positive tone and negative tone. Positive tone photoresists increase in solubility when exposed to light, facilitating the removal of exposed areas during the development stage while preserving unexposed regions to create precise patterns. This characteristic can form structures formed in later steps of the process. Negative tone photoresists, on the other hand, become less soluble upon light exposure, allowing unexposed regions to be removed while retaining the structure in exposed areas. This property can be used for creating features where the exposed regions must remain intact. In some embodiments, the mask layer 96 may be made of materials such as silicon oxide, silicon nitride, or a combination of these substances. These materials can be deposited using various methods, including physical vapor deposition (PVD), chemical vapor deposition (CVD), or sputter deposition, selected for their high etching selectivity, in relation to previously applied layers such as the source/drain contact layer 93, ensuring that material removal processes target only the intended areas, preserving the integrity of the rest of the device.

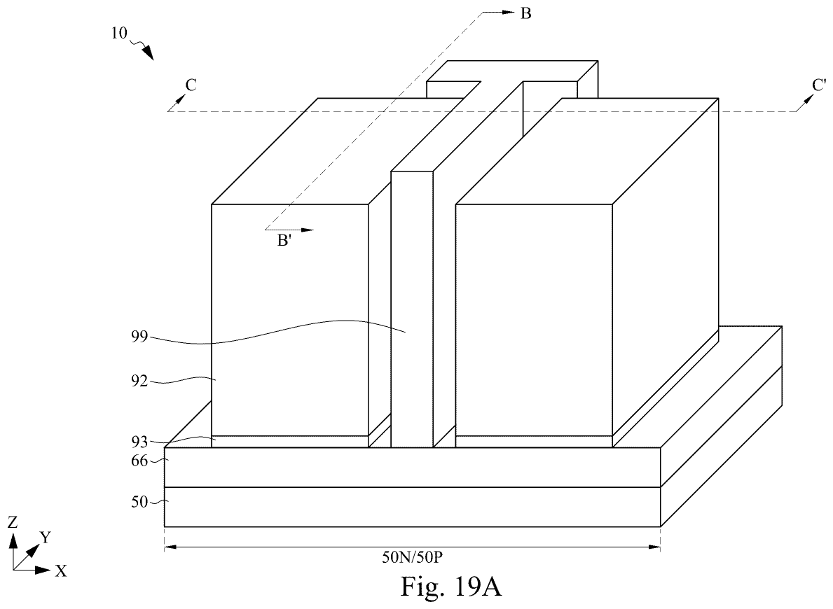

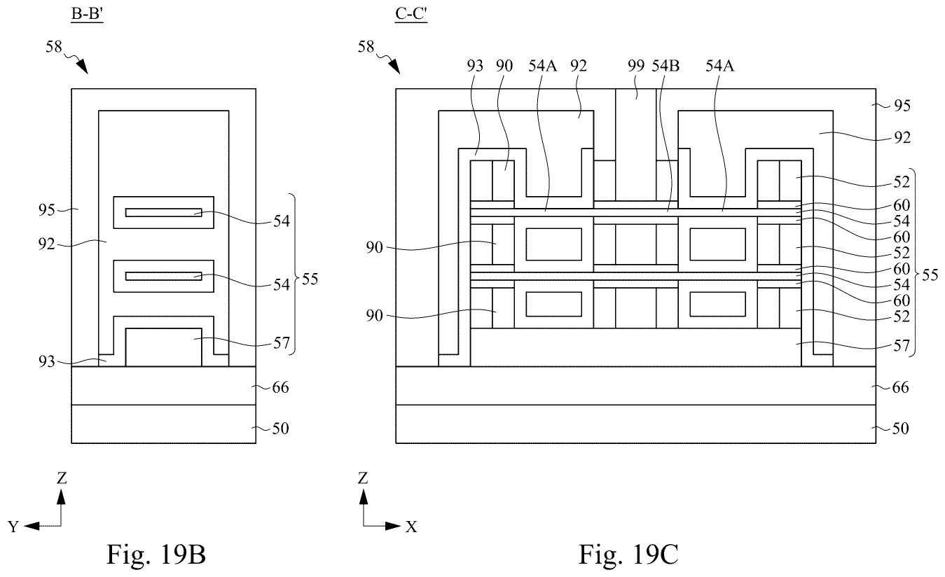

Once deposited, the mask layer 96 undergoes a patterning process through advanced photolithography and etching techniques to form opening 98. This patterning is applied for aligning with the source/drain region and the channel regions of the nanostructures 54. The areas exposed by the mask layer 96 are as they define the scope for forming the subsequent source/drain metals 92, as shown in FIGS. 15A-15C. In contrast, the regions that remain covered by mask layer 96 are intended for later development as gate structures, as detailed in FIGS. 19A-19C. The mask layer 96 can be positioned so that its lengthwise orientation is perpendicular to that of the nanostructures 55.

Reference is made to FIGS. 15A-15C. Source/drain metals 92 can be formed over the structure outlined in FIGS. 14A-14C, specifically within the openings 98, establishing electrical pathways and connectivity within the semiconductor device. Initially, a source/drain metal material is deposited over the entire structure, ensuring that the source/drain openings 98 are completely filled with the metal for providing electrical continuity and forming an interface with the underlying source/drain regions 54A. Following the metal deposition, a chemical mechanical polishing (CMP) process can be employed to remove the excess source/drain metal material present above the mask layer 9 for achieving a planar, uniform surface and is integral in delineating the source/drain metals 92 into discrete segments that snugly encapsulate individual source/drain regions 54A. The CMP process not only enhances surface flatness but also ensures patterning by separating the metal into well-defined components that correspond to the underlying active areas.

Once the CMP process is completed, the mask layer 96 can be removed to expose the isolated source/drain metal 92. If the mask layer 96 is made of photo materials, a lift-off technique can be applied for its removal. The lift-off process involves dissolving the underlying photoresist layer, which allows the mask material to be lifted away, effectively removing it without the need for additional etching steps. In cases where the mask layer is composed of different materials, such as silicon oxide or silicon nitride, selective etching techniques tailored to the mask material's composition can be employed. Wet etching with hydrofluoric acid or dry etching using plasma methods can effectively remove these materials without affecting the source/drain metals or underlying structures.

In some embodiments, the source/drain metals 92 can be formed from a variety of conductive materials, each selected for its properties to meet the performance of the device. In some embodiments, the source/drain metals 92 can include copper (Cu), tungsten (W), aluminum (Al), titanium (Ti), cobalt (Co), the like, or combinations thereof. The deposition of the source/drain metals 92 can be conducted through, such as physical vapor deposition (PVD), chemical vapor deposition (CVD), or other suitable deposition process. In some embodiments, electroplating can be another method that can be used for depositing conductive layers, enabling buildup of the source/drain regions in alignment with the device specifications. In some embodiments, the source/drain metal 92 and the source/drain contact layer 93 can be collectively referred to as a source/drain contact, a source/drain pattern, a source/drain layer, or a source/drain structure. In some embodiments, the source/drain metal 92 can wrap around four sides of the nanostructure 54. In some embodiments, a portion of the source/drain metal 92 can extend below the nanostructure 54 and spans two edge of a bottom surface of the nanostructure 54 along a lengthwise direction of the gate structure (see FIG. 19A). In some embodiments, a portion of the source/drain metal 92 can be positioned below the nanostructure 54 (or a lowermost one of the nanostructure 54). In some embodiments, the source/drain metal 92 can be interchangeable referred to as a metal contact, a metal film, a metal layer, a metal pattern, or a conductive layer.

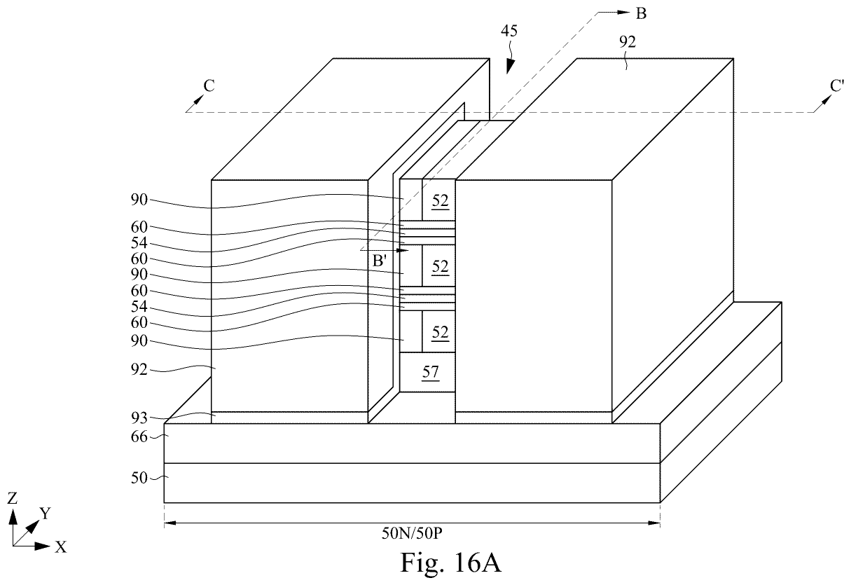

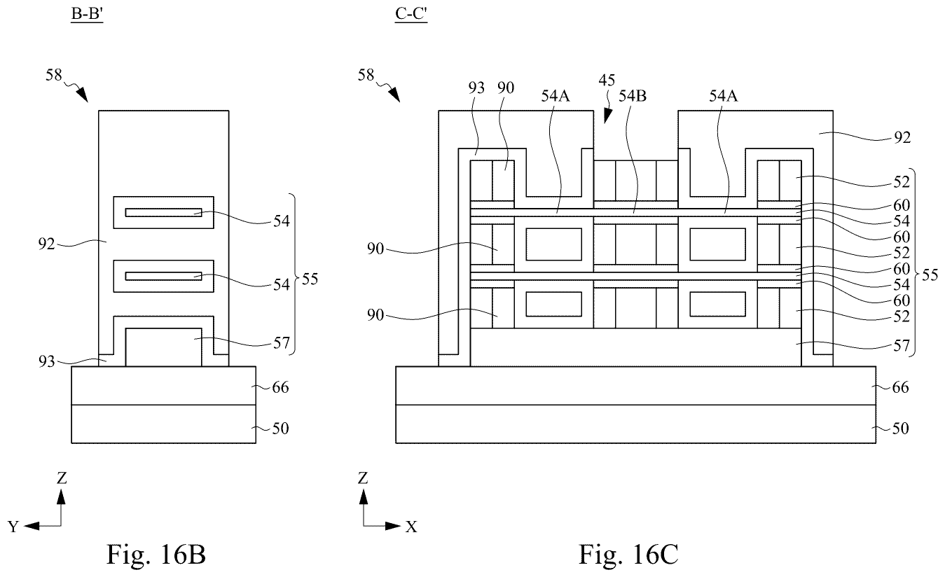

Reference is made to FIGS. 16A-16C. The portions of the source/drain contact layer 93 that are exposed by the source/drain metals 92 are moved to form an opening 45. Specifically, After the deposition of the source/drain metals 92, the source/drain contact layer 93 in the channel area must be removed to prevent interference with subsequent processing steps. As shown in FIG. 16A-16C, this removal step exposes the underlying nanostructures 52, inner spacers 90, and the dielectric layer 66. During this process, the source/drain metals 92 can serve as a mask, protecting specific regions beneath them from the removal or etching procedures. The removal of the exposed portions of the source/drain contact layer 93 can be accomplished using selective etching techniques. These methods may include chemical wet etching, which involves an etchant specifically selected to target and dissolve the material of the adhesive layer without affecting other components. Alternatively, dry etching processes, like an atomic layer etching (ALE) or a reactive ion etching (RIE), can be employed to selectively strip away the exposed source/drain contact layer 93. In some embodiments, the nanostructures 52, the inner spacers 90, and the dielectric layer 66 may remain intact and are not removed during this process due to their distinct material compositions and the selective nature of the etching process. The etchant used is chosen for its high selectivity, meaning it is effective at removing the source/drain contact layer 93 but does not react significantly with the materials constituting the nanostructures 52, inner spacers 90, and dielectric layer 66. Additionally, these layers can be designed with materials resistant to the specific etching conditions used to remove the source/drain contact layer 93, thereby preserving their integrity and functionality throughout the process, ensuring that the exposed components remain unchanged and continue to serve their roles in the semiconductor device.

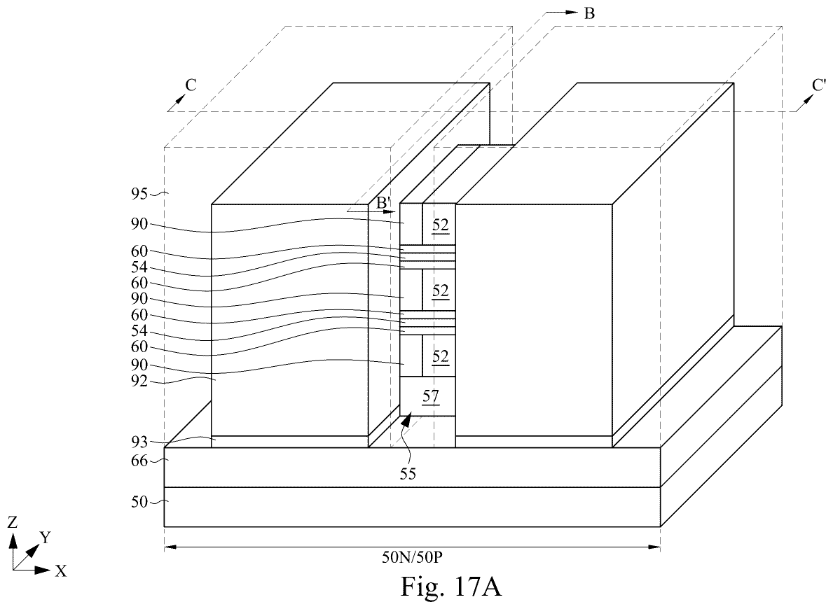

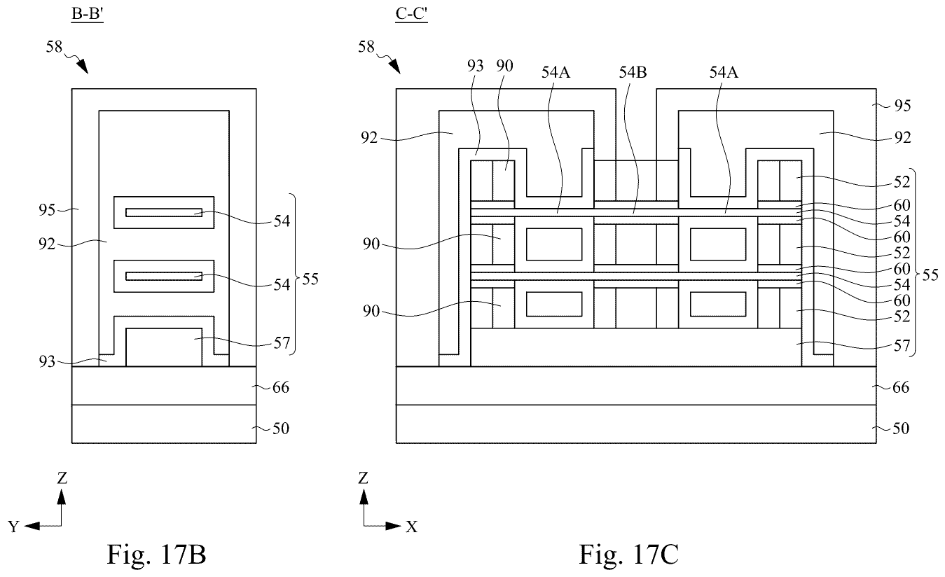

Reference is made to FIGS. 17A-17C. An interlayer dielectric (ILD) layer 95 can be deposited over the structure illustrated in FIGS. 15A-15C. The ILD layer 95 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. After the ILD layer 95 is deposited, a planarization process, such as a CMP, may be performed to level the top surface of the ILD layer 95. Subsequently, the ILD layer 95 can be etched to form openings 97 exposing surfaces of the nanostructures 55. The openings 97 may be formed by etching using an anisotropic etching process, such as RIE, NBE, or the like. A mask, such as a photoresist, may be formed and patterned over the ILD layer 95 to mask portions of the ILD layer 95 from the etching process.

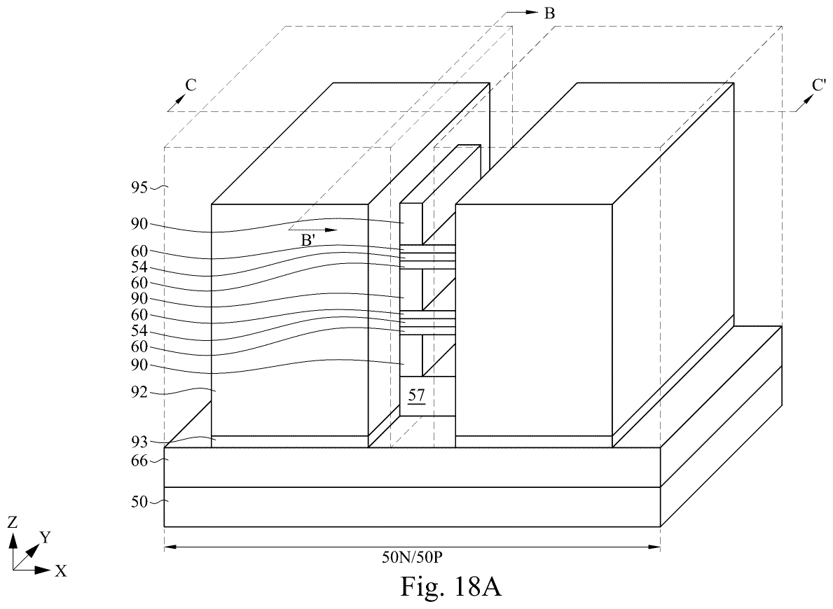

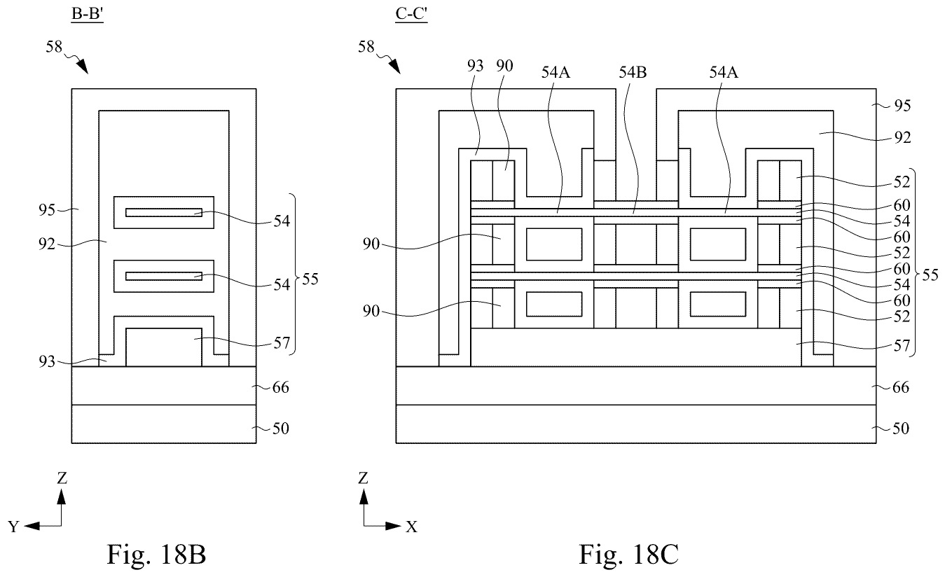

Reference is made to FIGS. 18A-18C. The nanostructures 52 can be removed in an etching process to expand the opening 97. During the removal, the nanostructures 60 may be used as etch stop layers when the nanostructures 52 are etched. Each opening 97 can expose and/or overlies portions of the channel regions 54B on the nanostructures 54. The nanostructures 52 can be etched by any acceptable etching process that selectively etches the material of the nanostructures 52 at a faster rate than the material of the nanostructures 54, the nanostructures 60, and the nanostructure 57. In some embodiments, the etching may be isotropic. For example, when the nanostructures 52 can be formed of silicon nitride and/or silicon oxide and the nanostructures 60 and/or 57 can be formed of high-k dielectric material, the etching process may be a dry etch using carbon tetrafluoride (CF4) gas or the like. In some embodiments, the removing of the remaining portions of the nanostructures 52 can be interchangeably referred to as a channel releasing process.

During the etching process to remove the nanostructures 52 and expand the openings 97, the nanostructures 60 can serve as etch stop layers. This selective etching process can ensures that the nanostructures 52 are removed more quickly than the materials comprising the nanostructures 54, 60, and 57. As a result of their resilience to the etching conditions, the nanostructures 60 remain intact. Given this intactness, the nanostructures 60 can function as gate dielectrics in subsequent process stages. This eliminates additional formation of a separate gate dielectric layer over the channel regions 54B. Instead, manufacturers can proceed directly with forming the gate electrode atop these existing nanostructures 60, streamlining the fabrication process and preserving the integrity and functionality of the channel regions 54B.

Reference is made to FIGS. 19A-19C. Gate electrode layer 99 can be formed for replacement gates. The gate electrode layer 99 can be deposited over the structure as shown in FIGS. 18A-18C and in the opening 97. The gate electrode layer 99 may include a metal-containing material such as titanium nitride, titanium oxide, tantalum nitride, tantalum carbide, cobalt, ruthenium, aluminum, tungsten, combinations thereof, or multi-layers thereof. For example, although single layer the electrode layer 99 are illustrated in FIGS. 19A-19C, the gate electrode layer 99 may comprise any number of liner layers, any number of work function tuning layers, and a fill material. Any combination of the layers which make up the gate electrode layer 99 may be deposited in the n-type region 50N between adjacent ones of the nanostructures 54 and between the nanostructures 54 and 57, and may be deposited in the p-type region 50P between adjacent ones of the nanostructures 54.

After the filling of the opening 97, a planarization process, such as a CMP, may be performed to remove the excess portions of the material of the gate electrode layer 99, which excess portions are over the top surface of the ILD layer 95. The remaining portions of material of the gate electrode layer 99 thus form replacement gate structures of the resulting nano-FETs. In some embodiments, the gate electrode layer 99 and the nanostructures 60 may be collectively referred to as “gate structures.” In some embodiments, the gate structure can be interchangeable referred to as a gate layer, a gate strip, a gate pattern, a gate line, or a gate structure.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a wraparound source/drain contact formation process, which increases the contact area between the 2D material source/drain region and the source/drain metal layer. Specifically, a protection layer (e.g., nanostructure 60 shown in FIGS. 11A-12C) can be formed to protect the channel area during the etching and sheet release processes in the source/drain area. Subsequently, a sheet release process (see FIG. 11A-11C) can be performed in source/drain area, creating a suspended nanosheet structure (e.g., source/drain region 54A) before the source/drain metal deposition (e.g., source/drain metals 92 shown in FIGS. 15A-15C). Subsequently, a specific dry etching (FIGS. 12A-12C) to pattern the protection layer and release the source/drain region 54A from the protection layer for the wraparound contact. The source/drain metal 92 can be formed over the source/drain region 54A to form a wraparound contact profile that maximizes the interaction between the source/drain 92 metal and the source/drain region 54A, which in turn allows for reducing resistance.

In some embodiments, a method includes providing a stacked structure of alternating two-dimensional (2D) material layers and dielectric layers; selectively removing first portions of the dielectric layers around source/drain regions of the 2D material layers; forming contact layers wrapping around the source/drain regions of the 2D material layers; forming source/drain metals over the contact layers; selectively removing second portions of the dielectric layers around channel regions of the 2D material layers; forming a gate electrode wrapping around the channel region of the 2D material layers, wherein the gate electrode is positioned laterally between the source/drain metals. In some embodiments, forming the source/drain metals is performed such that a portion of one of the source/drain metals interposes between adjacent two of the 2D material layers. In some embodiments, selectively removing the first portions of the dielectric layers is performed such that opposite ends of one the source/drain regions of the 2D material layers remains embedded within the dielectric layers of the stacked structure. In some embodiments, the stacked structure further comprises first and second protection layers sandwiching one of the 2D material layers. In some embodiments, after selectively removing the first portions of the dielectric layers and prior to forming the contact layers, selectively removing portions of the first and second protection layers around the source/drain regions of the 2D material layers. In some embodiments, the first and second protection layers are made of a high-k dielectric material. In some embodiments, forming the contact layers comprising: depositing a metal film over the stacked structure; etching the metal film to form the contact layers, wherein the source/drain metals act as an etch mask. In some embodiments, forming the contact layers is performed by using an atomic layer deposition. In some embodiments, the contact layers comprise titanium nitride. In some embodiments, the method further includes forming an inner spacer around one of the 2D material layers, such that after forming the source/drain metals and the gate electrode, the inner spacer is between one of the source/drain metals and the gate electrode.

In some embodiments, a method includes forming a two-dimensional (2D) material nanostructure; forming a dielectric spacer surrounding the 2D material nanostructure; forming a contact layer conformally wrapping around a source/drain region of the 2D material nanostructure; forming a source/drain metal over the contact layer and wrapping around the source/drain region of the 2D material nanostructure; forming a gate structure wrapping around a channel region of the 2D material nanostructure, wherein the dielectric spacer is positioned between the contact layer and the gate structure. In some embodiments, a portion of the source/drain metal extends below 2D material nanostructure and spans two edge of a bottom surface of the 2D material nanostructure along a lengthwise direction of the gate structure. In some embodiments, the gate structure comprises: a gate dielectric conformally wrapping around the channel region of the 2D material nanostructure; and a gate electrode over the gate dielectric, and the gate dielectric interfaces with a horizontal surface of the dielectric spacer. In some embodiments, the contact layer further extends along a sidewall of the dielectric spacer. In some embodiments, the contact layer is made of a titanium-containing material.

In some embodiments, a semiconductor structure includes a gate structure, a nanostructure, a first contact layer, and a first source/drain metal. The nanostructure extends through the gate structure. The first contact layer is separated from the gate structure, wherein from a cross-sectional view taken along a lengthwise direction of the gate structure, the first contact layer wraps around four sides of the nanostructure. The first source/drain metal is over the first contact layer, wherein from the cross-sectional view, the first source/drain metal wraps around the four sides of the nanostructure. In some embodiments, the nanostructure is made of a two-dimensional material. In some embodiments, a portion of the first source/drain metal is positioned below the nanostructure. In some embodiments, the semiconductor structure further includes a second contact layer wrapping around the four sides of the nanostructure on an opposing side of the gate structure to the first contact layer; and a second source/drain metal formed over the second contact layer and wrapping around the four sides of the nanostructure. In some embodiments, the semiconductor structure further includes an inner spacer surrounding the nanostructure, wherein the inner spacer separates the first source/drain metal from the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a stacked structure of alternating two-dimensional (2D) material layers and dielectric layers;
selectively removing first portions of the dielectric layers around source/drain regions of the 2D material layers;
forming contact layers wrapping around the source/drain regions of the 2D material layers;
forming source/drain metals over the contact layers;
selectively removing second portions of the dielectric layers around channel regions of the 2D material layers; and
forming a gate electrode wrapping around the channel region of the 2D material layers, wherein the gate electrode is positioned laterally between the source/drain metals.

2. The method of claim 1, wherein forming the source/drain metals is performed such that a portion of one of the source/drain metals interposes between adjacent two of the 2D material layers.

3. The method of claim 1, wherein selectively removing the first portions of the dielectric layers is performed such that opposite ends of one the source/drain regions of the 2D material layers remains embedded within the dielectric layers of the stacked structure.

4. The method of claim 1, wherein the stacked structure further comprises first and second protection layers sandwiching one of the 2D material layers.

5. The method of claim 4, wherein after selectively removing the first portions of the dielectric layers and prior to forming the contact layers, selectively removing portions of the first and second protection layers around the source/drain regions of the 2D material layers.

6. The method of claim 4, wherein the first and second protection layers are made of a high-k dielectric material.

7. The method of claim 1, wherein forming the contact layers comprising:
depositing a metal film over the stacked structure; and
etching the metal film to form the contact layers, wherein the source/drain metals act as an etch mask.

8. The method of claim 1, wherein forming the contact layers is performed by using an atomic layer deposition.

9. The method of claim 1, wherein the contact layers comprise titanium nitride.

10. The method of claim 1, further comprising:
forming an inner spacer around one of the 2D material layers, such that after forming the source/drain metals and the gate electrode, the inner spacer is between one of the source/drain metals and the gate electrode.

11. A method, comprising:
forming a two-dimensional (2D) material nanostructure;
forming a dielectric spacer surrounding the 2D material nanostructure;
forming a contact layer conformally wrapping around a source/drain region of the 2D material nanostructure;
forming a source/drain metal over the contact layer and wrapping around the source/drain region of the 2D material nanostructure; and
forming a gate structure wrapping around a channel region of the 2D material nanostructure, wherein the dielectric spacer is positioned between the contact layer and the gate structure.

12. The method of claim 11, wherein a portion of the source/drain metal extends below 2D material nanostructure and spans two edge of a bottom surface of the 2D material nanostructure along a lengthwise direction of the gate structure.

13. The method of claim 11, wherein the gate structure comprises:
a gate dielectric conformally wrapping around the channel region of the 2D material nanostructure; and
a gate electrode over the gate dielectric, and the gate dielectric interfaces with a horizontal surface of the dielectric spacer.

14. The method of claim 11, wherein the contact layer further extends along a sidewall of the dielectric spacer.

15. The method of claim 11, wherein the contact layer is made of a titanium-containing material.

16. A semiconductor structure, comprising:
a gate structure;
a nanostructure extending through the gate structure;
a first contact layer separated from the gate structure, wherein from a cross-sectional view taken along a lengthwise direction of the gate structure, the first contact layer wraps around four sides of the nanostructure; and
a first source/drain metal over the first contact layer, wherein from the cross-sectional view, the first source/drain metal wraps around the four sides of the nanostructure.

17. The semiconductor structure of claim 16, wherein the nanostructure is made of a two-dimensional material.

18. The semiconductor structure of claim 16, wherein a portion of the first source/drain metal is positioned below the nanostructure.

19. The semiconductor structure of claim 16, further comprising:
a second contact layer wrapping around the four sides of the nanostructure on an opposing side of the gate structure to the first contact layer; and
a second source/drain metal formed over the second contact layer and wrapping around the four sides of the nanostructure.

20. The semiconductor structure of claim 16, further comprising:
an inner spacer surrounding the nanostructure, wherein the inner spacer separates the first source/drain metal from the gate structure.
